(19) United States
(12) Patent Application Publication
(10) Pub. No.: US 2022/0151098 A1
(43) Pub. Date: May 12, 2022

(54) COOLING DEVICES FOR COOLING ELECTRONIC COMPONENTS WITH LIQUID COOLING COMPONENTS

(71) Applicant: Lenovo Enterprise Solutions (Singapore) Pte. Ltd., New Tech Park (SG)

(72) Inventors: Andrew Junkins, Research Triangle Park, NC (US); Paul Artman, Research Triangle Park, NC (US); Vinod Kamath, Research Triangle Park, NC (US)

(21) Appl. No.: 17/094,696

(22) Filed: Nov. 10, 2020

(51) Int. Cl. H05K 7/20

(52) U.S. Cl. CPC H05K 7/20245; H05K 7/20254

(57) ABSTRACT

Cooling devices for cooling electronic components with liquid cooling and associated methods thereof are disclosed. According to an aspect, a device includes a housing that defines an interior space. The device also includes an electronic component positioned in the interior space. The device also includes a liquid cooling component configured to engage the housing and the electronic component for cooling the electronic component and the interior space.

### TECHNICAL FIELD

The presently disclosed subject matter relates generally to cooling devices for electronic components. Particularly, the presently disclosed subject matter relates to electronic component cooling devices for housings containing an electronic component that include configurations for liquid cooling the electronic component with liquid cooling components.

### SUMMARY

The presently disclosed subject matter pertain to liquid cooling devices for electronic component housings.

According to an aspect, a device including a housing defining an interior space and configured to contain a liquid in the interior space. The device also includes an electronic component positioned in the interior space. The electronic component is also positioned within the liquid. The device also includes a liquid cooling component in heat transfer interface with such liquid and configured to receive a flow of an additional, second, liquid. Further, the device is configured to transfer the heat from the first liquid to that second liquid.

According to an aspect, a device including a housing defining a first interior space and configured to contain a first liquid in the first interior space. The device also includes an electronic component positioned in the first liquid in the first interior space. The device also includes a liquid cooling component defining a second interior space that is configured to contain a second liquid within the second interior space. The liquid cooling component is further in heat transfer interface with the first liquid and the second liquid and is configured to separate the first liquid from the second liquid. According to a further aspect, the device is configured to transfer the heat from the first liquid to that second liquid, to cool the electronic device.

The device contemplates a variety of configurations that allow for a liquid cooling component to transfer the heat from the electronic component and/or the liquid to the second liquid, and for the liquid to carry the heat away from the device, such as any known in the art but also comprising and not limited to closed fluid and liquid conduits, heat pipes, vapor chambers, coolant loops, cold plates and solid material heat-conductive components, and in such shapes and volumes to supplement or supplant existing cooling devices that do not comprise such components and/or liquids. Such existing devices that may be supplemented or supplanted may comprise open-housing air cooling components, for example.

Several exemplary embodiments comprise ones in which: a housing is sealed, water-tight, to facilitate a power supply housing; a liquid to fill a housing comprises dielectric cooling fluid; a liquid cooling component comprises a sealed, water-tight plenum; a liquid to fill such a cooling component having a plenum comprises water therein; a plenum comprises copper or brass construction; a plenum comprising a pathway for a liquid comprises inlet and outlet valves to an external cooling distribution system configured to remove or dissipate heat or receive or return liquid to the device or other devices via a manifold.

Embodiments further comprise exemplary forms of heat transfer interface, thermally coupling liquid cooling components to one another or in distinctly performing portions of an integrated device, conductive liquid to surface to liquid heat transfer, convective heat transfer through static volumes of fluid or liquid, dynamic flows of heated and cooled fluids or liquids in pathways or loops, convective heat transferred in gas to surface to liquid, and liquid-to-surface-to-gas heat transfer, etc.

### BRIEF DESCRIPTION OF THE DRAWINGS

The embodiments are illustrated by way of example and not limitation in the figures of the accompanying drawings in which like references indicate similar elements.

FIG. 1 is a top view of a section of an exemplary device including a housing, an electronic component positioned in the housing, a liquid cooling component, with the housing in a configuration for liquid cooling the electronic component with the liquid in accordance with embodiments of the present disclosure.

FIG. 2 is a top view of a section of an exemplary device including a housing, an electronic component positioned in the housing, a liquid cooling component in conductive heat interface with the electronic component and a liquid in the housing, and a liquid in the housing, with the housing in a configuration for liquid cooling the electronic component with the liquid in accordance with embodiments of the present disclosure.

FIG. 3A is a top view of an exemplary liquid cooling component for liquid cooling an electronic component, including a plenum portion and a heat conduit portion, in accordance with embodiments of the present disclosure.

FIG. 3B is a top view of a section of an exemplary liquid cooling component for liquid cooling an electronic component, including a plenum portion and a heat conduit portion containing a liquid in the plenum and heat conduit portions, the liquid in the portions being liquidly contiguous, in accordance with embodiments of the present disclosure.

FIG. 3C is a top view of a section of an exemplary liquid cooling component for liquid cooling an electronic component, including a plenum portion and a heat conduit portion configured to conductive heat interface with the electronic component, with the liquid cooling component containing a flow of the liquid and the heat conduit portion containing an amount of the liquid that is contiguous with the flow of the liquid, in accordance with embodiments of the present disclosure.

### DETAILED DESCRIPTION

The following detailed description is made with reference to the figures. Exemplary embodiments are described to illustrate the disclosure, not to limit its scope, which is defined by the claims. Those of ordinary skill in the art will recognize a number of equivalent variations in the description that follows.

Articles “a” and “an” are used herein to refer to one or to more than one (i.e. at least one) of the grammatical object of the article. By way of example, “an element” means at least one element and can include more than one element.

“About” is used to provide flexibility to a numerical endpoint by providing that a given value may be “slightly above” or “slightly below” the endpoint without affecting the desired result.

The use herein of the terms “including,” “comprising,” or “having,” and variations thereof is meant to encompass the elements listed thereafter and equivalents thereof as well as additional elements. Embodiments recited as “including,” “comprising,” or “having” certain elements are also contemplated as “consisting essentially of” and “consisting” of those certain elements.

Recitation of ranges of values herein are merely intended to serve as a shorthand method of referring individually to each separate value falling within the range, unless otherwise indicated herein, and each separate value is incorporated into the specification as if it were individually recited herein. For example, if a range is stated as between 1%-50%, it is intended that values such as between 2%-40%, 10%-30%, or 1%-3%, etc. are expressly enumerated in this specification. These are only examples of what is specifically intended, and all possible combinations of numerical values between and including the lowest value and the highest value enumerated are to be considered to be expressly stated in this disclosure.

Unless otherwise defined, all technical terms used herein have the same meaning as commonly understood by one of ordinary skill in the art to which this disclosure belongs.

The described features, structures, or characteristics may be combined in any suitable manner in one or more embodiments. In the following description, numerous specific details are provided, to provide a thorough understanding of embodiments of the disclosed subject matter. One skilled in the relevant art will recognize, however, that the disclosed subject matter can be practiced without one or more of the specific details, or with other methods, components, materials, etc. In other instances, well-known structures, materials, or operations are not shown or described in detail to avoid obscuring aspects of the disclosed subject matter.

As referred to herein, the terms “computing device” and “entities” should be broadly construed and should be understood to be interchangeable. They may include any type of computing device, for example, a server, a desktop computer, a laptop computer, or the like.

While the embodiments have been described in connection with the various embodiments of the various figures, it is to be understood that other similar embodiments may be used, or modifications and additions may be made to the described embodiment for performing the same function without deviating therefrom. Therefore, the disclosed embodiments should not be limited to any single embodiment, but rather should be construed in breadth and scope in accordance with the appended claims.

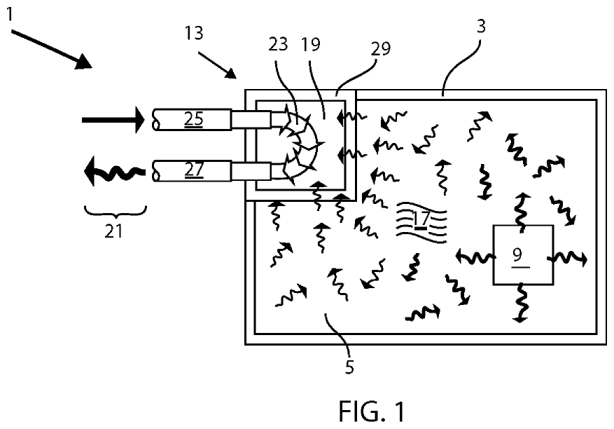

Referring now to FIG. 1, the figure shows an exemplary electronic component cooling device 1 including a housing 3 defining an interior space 5 that is configured to contain a first liquid 17 therein. An electronic component 9 is positioned in the housing 3, within the liquid 17. FIG. 1 further shows a liquid cooling component 13 in heat transfer interface with the first liquid 17. The liquid cooling component 13 is configured to transfer heat away from the first liquid 17. The liquid cooling component 13 is also configured to receive a flow of a second liquid 21 and to transfer the heat from the first liquid 13 to the second liquid 21.

As stated above, some exemplary housings adequate to facilitate defining an interior space and configured to contain a liquid in this manner comprise sealed, water-tight construction. Some adequate sealed, water-tight housings comprise metal or composite vessels formed by welding, folding, pressing, casting, or supplemented with a sealing material or adhesive, such as silicone or rubber.

The device 1 cools by operating the liquid cooling component 13: transferring heat away from the electronic component 9 to the liquid 17 in the housing 3, and carrying the heat produced by the electronic component 9 through the liquid 17 to a site of heat transfer interface with the liquid cooling component 13, such that the heat is removed from the liquid 17, into the liquid cooling component 13, for being transferred out of the device 1, thereafter. In the present FIG. 1, heat is shown being transferred from the electronic component 9 into and through the liquid 17 by convection. The heat is then convectively transferred from the liquid 17 into the liquid cooling component 13. As stated above, some exemplary liquids and fluids adequate to transfer heat convectively in this manner comprise dielectric cooling fluids. One such adequate fluid is 3M NOVEC fluid,

Irrespective of the flow of the second liquid 21 the liquid cooling component 13 comprises a second interior space 19 for containing a second liquid 21. The liquid 17 in the housing 3 is contained in the interior space 5, which is outside the liquid cooling component 13. Thereby, the liquid 17 is in convective heat interface with both the electronic component 9 and a plenum portion 29 of the liquid cooling component 13, for cooling the electronic component 9. The plenum portion 29 is also in convective heat transfer with the second liquid 21 in the second interior space 19. By the plenum portion 29 demarcating the separate interior spaces 5 and 19, the second interior 19 is configured to separate the first liquid 17 from the second liquid 21, and provides a pathway 23 for the second liquid 21 to flow therethrough, from an inlet 25 to an outlet 27, for removal of heat outside the liquid cooling component 13, without requiring physical movement of the first liquid 17. Thereby, the liquid cooling component 13 is configured to receive heat produced by the electronic component 9 and to transfer the heat to the second liquid 21 for removing the received heat via the outlet 27.

As stated above, an exemplary plenum adequate to demarcate two separate spaces and be filled with a liquid to provide a pathway therein and provide convective heat transfer with liquids contained in the spaces comprises sealed, water-tight construction. Some adequate sealed, water-tight plenums comprise copper or brass construction.

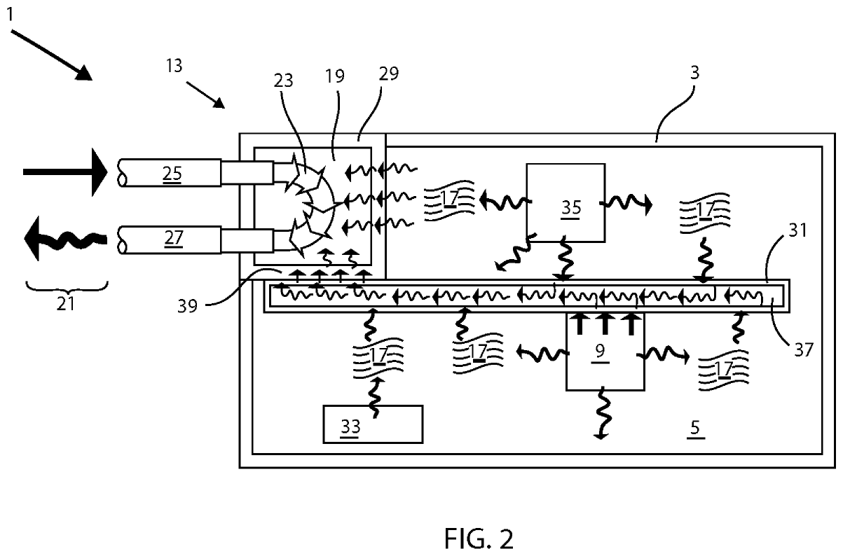

Referring now to FIG. 2, the device 1 is configured to a second configuration for liquid cooling an electronic component 9 with a liquid 17, similar to the embodiment shown in FIG. 1. The liquid cooling component 13 shown here, though, is also in conductive heat interface with the electronic component 9.

The liquid cooling component 13 is in conductive heat interface with the electronic component 9 by comprising a heat conduit 31 in conductive heat interface with the electronic component 9. Also, the heat conduit 31 extends through the liquid 17 in the housing 3, traversing the interior 5, such that it is in convective heat interface with the liquid 17. The liquid 17 is in convective heat interface with the electronic component 9, but the liquid 17 is also in convective heat interface with additional electronic components 33 and 35. Thereby, the heat conduit 31 is in convective heat interface with all of the electronic components 9, 33, and 35.

As stated above, some exemplary heat conduits adequate to transfer heat in this manner may comprise closed fluid and liquid conduits, heat pipes, vapor chambers, coolant loops, cold plates, and solid material heat-conductive components. Some such adequate heat conduits include a copper or other heat-conductive metal elongate vessel, such as a gas-encapsulating- or liquid-encapsulating-heat pipe.

Here, the heat conduit 31 is in conductive heat interface with the plenum portion 29 proximate a cold plate, a conductive wall 39. Thereby, the liquid cooling component 13 is configured to receive heat from the heat conduit 31 (which was heat produced by the electronic components 9, 33, and 35), and to transfer the heat to the second liquid 21 for removing the received heat via the outlet 27. Stated differently, the conductive wall 39 facilitates a configuration of a cold plate that is configured to transfer the heat from the heat conduit 31 to the second fluid 21 and/or a configuration of a cold plate that is configured to transfer heat from the first liquid 17 to the second liquid 21.

Specifically, the heat conduit 31 in FIG. 2 is an exemplary embodiment of a heat conduit portion of the liquid cooling component 13, which also includes the plenum portion 29. Here, the heat conduit 31 portion contains a heat transfer fluid 37 throughout the conduit 31 portion, and the flow of the second liquid 21 is separated from the heat transfer fluid 37 by the conductive wall 39. The conductive wall 39, by conducting between the heat conduit portion 31 and the plenum portion 29 that contains and is in convective heat transfer with the liquid 21, facilitates a convective heat transfer to the second liquid 21. Thereby, the heat conduit 31 is in conductive heat interface with the conductive contact wall 39, such that the heat conduit 31 is configured to transfer heat of the electronic component 9 (and of electronic components 33 and 35) to the flow of the second liquid 21.

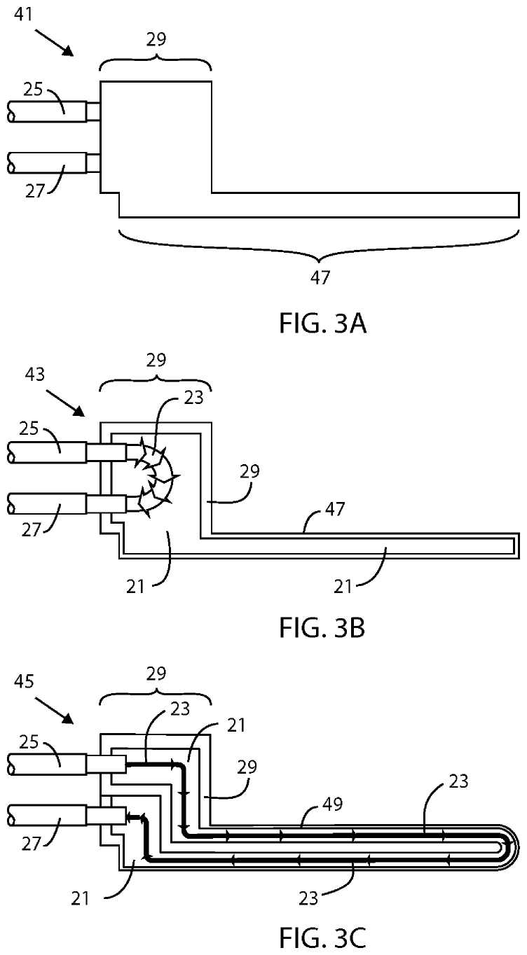

Referring now to FIGS. 3A-C, what are shown are exemplary types of liquid cooling components 41, 43, and 45.

FIG. 3A shows a top view of a liquid cooling component 41 similar to the liquid cooling component 13 shown in FIG. 2, comprising a plenum portion 29 and a heat conduit portion 47 that is similar to the heat conduit 31 of FIG. 2.

Referring now to FIG. 3B, the figure shows an exemplary liquid cooling component 43 having similar proportions to the liquid cooling components 13 and 41 shown in FIGS. 2 and 3A, respectively. Similarly to the plenum portion 29 of FIG. 2, the plenum portion 29 contains a liquid (second liquid 21, FIG. 2). Here, though, both the plenum portion 29 and heat conduit portion 47 are configured to contain the liquid 21 such that the portions 29 and 47 are liquidly contiguous throughout the liquid 21 in the plenum portion 29 and the liquid 21 in the heat conduit portion 47. The distinction from FIG. 2 is that liquid cooling component 43 is one in which the liquid 21 is not limited to an interior of the plenum portion (see second interior 19, FIGS. 1 and 2). A pathway 23 shown here, flowing between an inlet 25 and outlet 27, is merely exemplary and is similar to the pathway of FIG. 2, but the embodiment shown in FIG. 3B is not limited to pathways of this particular shape. As the second liquid 21 extends contiguously through the plenum portion 29 and the heat conduit portion 47, such that they are liquidly contiguous, other contemplated exemplary embodiments comprise ones in which the pathway 23 traverses the liquid 21 closer to and/or within the heat conduit 47.

Referring now to FIG. 3C, the figure shows an exemplary liquid cooling component 45 having a similarly proportioned plenum portion 29 to the liquid cooling components 13, 41, and 43, shown in FIGS. 2, 3A, and 3B, respectively. However, while the liquid cooling component 45 comprises a heat conduit portion 49 which is configured to conductive heat interface with the electronic component (9, FIG. 2), it has a distinct shape from conduits and conduit portions 31 and 47. Here, the liquid cooling component 45 contains a flow of a second liquid 21 that continues through a heat conduit portion 49 containing an amount of the second liquid 21 that is contiguous throughout.

Specifically, the liquid cooling component 45 in FIG. 3C comprises a heat conduit portion 49 that has a looplike construction. Similarly to FIGS. 1, 2, and 3B, the liquid cooling component 45 provides a pathway 23 for the second liquid 21 to flow from an inlet 25 to an outlet 27, for removal of heat outside the liquid cooling component 45. Stated differently, the liquid cooling component 45 comprises an inlet 25 and an outlet 27 and a liquid loop configured to contain the second liquid 21 in a path 23 from the inlet 25 to the outlet 27 for removal of the heat from the heat conduit 49 to an outside of the liquid cooling component 45. Alternately, the liquid cooling component 13 comprises a loop portion 49 configured to contain at least a portion of the flow (such as in the pathway 23) of the second liquid 21.

Not depicted here but also contemplated are exemplary embodiments which provide a looplike construction for a liquid cooling devices that comprise a heat conduit or heat conduit portion with a marginal plenum or without any plenum, such as ones which comprise an inlet and an outlet to the heat conduit directly, rather than through a plenum.

While the embodiments have been described in connection with the various embodiments of the various figures, it is to be understood that other similar embodiments may be used, or modifications and additions may be made to the described embodiment for performing the same function without deviating therefrom. Therefore, the disclosed embodiments should not be limited to any single embodiment, but rather should be construed in breadth and scope in accordance with the appended claims.

What is claimed is:

1. An electronic device comprising:
a liquid cooling component comprising a heat conduit and a plenum portion having plenum walls, the heat conduit being in conductive heat transfer with at least one plenum wall;
a housing having housing walls;
the plenum walls and housing, walls cumulatively defining a first interior space within the housing and configured to contain a first liquid within the first interior space;
the plenum walls defining a second interior space within the plenum portion and configured to contain a second liquid within the second interior space;
an electronic component positioned in the first interior space within the first liquid; and
wherein the liquid cooling component is in convective heat transfer interface with the first liquid and configured to transfer heat away from the first liquid by at least one of the plenum walls being in convective heat transfer interface with the first liquid and by the heat conduit being in convective heat transfer interface with the first liquid, and
wherein the liquid cooling component is in conductive heat transfer interface with the electronic component and configured to transfer heat away from the electronic component by the heat conduit being in conductive heat transfer interface with the electronic component, wherein the liquid cooling component is configured to receive a flow of the second liquid and provide a pathway for the flow of the second liquid through the plenum portion, between an inlet and an outlet and to convectively transfer the heat from the first liquid to the second liquid, for removal of the heat from the heat conduit to an outside of the liquid cooling component.

2. (canceled)

3. (canceled)

4. (canceled)

5. (canceled)

6. (canceled)

7. (canceled)

8. (canceled)

9. The electronic device of claim 17, wherein the pathway comprises a liquid loop configured to contain the second liquid in a path that is contiguous with the heat conduit.

10. The electronic device of claim 1, wherein the liquid cooling component comprises a cold plate configured to transfer the heat from the first liquid to the second liquid.

11. (canceled)

12. (canceled)

13. (canceled)

14. The electronic device of claim 1, wherein the liquid cooling component comprises a loop portion configured to contain at least a portion of the flow of the second liquid.

15. (canceled)

16. (canceled)

17. (canceled)

18. (canceled)

19. (canceled)

20. (canceled)

21. An electronic device comprising:
A housing, a liquid cooling component, and an electronic component,
wherein the housing comprises housing walls and the liquid cooling component comprises a plenum portion and a heat conduit, the plenum portion comprising plenum walls,
the housing and liquid cooling component arranged such that the plenum walls and housing walls define both a first interior space configured to contain a first liquid within the housing and an adjacent second interior space that is configured to contain a second liquid within the plenum portion,
wherein at least one of the plenum walls is in convective heat transfer interface with the first liquid and is in convective heat transfer interface with the second liquid, the plenum portion being configured to provide a pathway for a flow of the second liquid through the second interior space, between an inlet and an outlet,
the electronic component and the heat conduit being positioned in the first interior space, within the first liquid the electronic component being at a position separated from the plenum portion by the first liquid and the heat conduit in conductive heat transfer with at least one plenum wall, extending away from the plenum portion, through the first liquid, to the electronic component, to contact the electronic component and be in conductive heat transfer interface therewith,
such that the device is configured to convectively transfer heat away from the electronic component to the first liquid and conductively transfer heat away from the electronic component to the heat conduit to transfer heat from the first liquid to the heat conduit and at least one plenum wall by convective heat transfer, and to transfer heat from the heat conduit to at least one plenum wall by conductive heat transfer, to convectively transfer heat transferred to the plenum portion into the flow of the second liquid, for removal of the heat to an outside of the liquid cooling component.

22. The electronic device of claim 21, wherein the liquid cooling component comprises a cold plate configured to transfer the heat from the first liquid to the second liquid.

23. The electronic device of claim 21, wherein the liquid cooling component comprises a loop portion configured to contain at least a portion of the flow of the second liquid.

24. An electronic device comprising;
a liquid cooling component comprising a heat conduit and a plenum portion having plenum walls the heat conduit being in conductive heat transfer with at least one plenum wall;
a housing having housing walls;
the plenum walls and housing walls cumulatively defining a first interior space within the housing and configured to contain a first liquid within the first interior space;
the plenum walls defining a second interior space within the plenum portion and which is contiguous with the heat conduit the second interior and conduit thereby being configured to contain a second liquid within the second interior space and conduit;
an electronic component positioned in the first interior space within the first liquid; and
wherein the liquid cooling component is in convective heat transfer interface with the first liquid and configured to transfer heat away from the first liquid by at least one of the plenum walls being in convective heat transfer interface with the first liquid and by the heat conduit being in convective heat transfer interface with the first liquid, and
wherein the liquid cooling component is in conductive heat transfer interface with the electronic component and configured to transfer heat away from the electronic component by the heat conduit being in conductive heat transfer interface with the electronic component,
wherein the liquid cooling component is configured to receive a flow of the second liquid and provide a pathway for the flow of the second liquid through the plenum portion and the conduit, between an inlet and an outlet and to convectively transfer the heat from the first liquid to the second liquid, for removal of the heat from the heat conduit to an outside of the liquid cooling component.

25. The electronic device of claim 24, wherein the liquid cooling component comprises a loop portion configured to contain at least a portion of the flow of the second liquid.
